(19) United States
(12) Patent Application Publication
(10) Pub. No.: US 2026/0190762 A1
(43) Pub. Date: Jul. 2, 2026

(54) DISPLAY DEVICE

(71) Applicant: LG Display Co., Ltd., Seoul (KR)

(72) Inventor: JunJae LEE, Paju-si (KR)

(73) Assignee: LG Display Co., Ltd., Seoul (KR)

(21) Appl. No.: 19/431,105

(22) Filed: Dec. 23, 2025

(30) Foreign Application Priority Data
Dec. 31, 2024 (KR) 10-2024-0202699

(51) Int. Cl. H10K 59/80; H10K 102/00

(52) U.S. Cl. CPC H10K 59/87; H10K 2102/311

(57) ABSTRACT

In one or more examples, a display device includes a substrate, a display area in which a plurality of pixels is disposed, a first non-display area outside the display area, a bending area extending from one side of the first non-display area, a second non-display area connected to the bending area, a driving circuitry disposed on the substrate in the second non-display area, and a reinforcement plate disposed on the substrate in the second non-display area and surrounding the side portion of the driving circuitry. The reinforcement plate includes a first portion which is flat, and a second portion which extends from the first portion and is bent, and in which a plurality of holes are disposed.

### CROSS-REFERENCE TO RELATED APPLICATIONS

This application claims the benefit of and priority to Korean Patent Application No. 10-2024-0202699 filed on Dec. 31, 2024, in the Korean Intellectual Property Office, the entire contents of which are incorporated herein by reference for all purposes.

### BACKGROUND

### 1. Technical Field

The present disclosure relates to a display device, and particularly to, for example, without limitation, a display device with improved reliability.

### 2. Description of Related Art

Currently, as it enters a full-fledged information era, the field of display devices that visually display electrical information signals is rapidly developing, and research is being conducted to develop performances such as thinning, weight reduction, and low power consumption for various display devices.

Among these various display devices, a light emitting display device is a self-emitting display device, and unlike a liquid crystal display device, a separate light source is not required, so that the light emitting display device may be manufactured to have a light weight and a small thickness. In addition, the light emitting display device is advantageous in terms of power consumption because the light emitting display device operates at a low voltage. Further, the light emitting display device is expected to be utilized in various fields because the light emitting display device is excellent in color implementation, a response speed, a viewing angle, and a contrast ratio (CR).

The description of related art should not be considered prior art merely because it is mentioned in or associated with this section. The description of related art includes information that describes one or more aspects of the subject technology, and the description in this section does not limit the scope of the present disclosure.

### SUMMARY

An aspect of the present disclosure provides a display device which minimizes concentration of stress on a partial area in a structure in which a bezel area is bent in a curved shape.

Another aspect of the present disclosure provides a display device capable of improving rigidity of a reinforcement plate in a structure in which a bezel area is bent in a curved shape.

Still another aspect of the present disclosure provides a display device which improves reliability by minimizing a moisture penetration failure.

Aspects of the present disclosure are not limited to the above-mentioned aspects, and other aspects, which are not mentioned above, can be clearly understood by those skilled in the art from the present disclosure.

According to one or more example embodiments of the present disclosure, a display device includes a substrate, a display area in which a plurality of pixels is disposed, a first non-display area outside the display area, a bending area extending from one side of the first non-display area, a second non-display area connected to the bending area, a driving circuitry disposed on the substrate in the second non-display area and a reinforcement plate disposed on the substrate in the second non-display area and surrounding the side portion of the driving circuitry, and the reinforcement plate includes a first portion which is flat, and a second portion which extends from the first portion and is bent, and in which a plurality of holes are disposed.

A display device one or more example embodiments of the present disclosure includes a substrate, a display area including a first display area having a flat surface and a second display area having a curved surface, a first non-display area outside the display area, a bending area extending from the first non-display area, a second non-display area extending from the bending area, a micro coating layer disposed in the first non-display area, the bending area, and the second non-display area on the substrate, and a reinforcement plate disposed in the second non-display area on the substrate, spaced apart from the micro coating layer, and having a plurality of holes disposed in an area overlapping the second display area.

Other detailed matters of the example embodiments are included in the detailed description and the drawings.

According to one or more aspects of the present disclosure, a hole is formed in a reinforcement plate disposed in an area in which a bezel area is bent in a curved shape so that even though the hole is bent in a curved shape, the stress is concentrated only in a partial area (or a localized area), which improves the reliability.

According to one or more aspects of the present disclosure, the portion where the hole of the reinforcement plate is not formed is disposed so as to correspond to the edge of the display device to ensure the rigidity of the reinforcement plate. Therefore, it is possible to minimize the damage to the display device by reducing the concentration of impact on the edge of the display device even with an external impact.

According to one or more aspects of the present disclosure, a hole of a reinforcement plate is filled with a molding member to minimize moisture permeation, reinforce rigidity, and enhance an adhesive force of the reinforcement plate.

The effects according to one or more aspects of the present disclosure are not limited to the contents described above, and other effects are included in the present disclosure.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further features, advantages, and aspects are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure.

FIG. 1 is a schematic view of a display device according to an example embodiment of the present disclosure.

FIG. 2 is a plan view of the display device according to the example embodiment of the present disclosure before bending.

FIG. 3 is a rear view of the display device according to the example embodiment of the present disclosure after bending.

FIG. 4 is an example of a cross-sectional view taken along the line A-A′ of FIG. 3.

FIG. 5 is an example of an enlarged plan view of a reinforcement plate of FIG. 3 and a part of a substrate on which the reinforcement plate is disposed.

FIG. 6 is an example of a plan view illustrating another shape of the reinforcement plate.

FIG. 7 is a plan view of a display device according to another example embodiment of the present disclosure.

FIG. 8 is a plan view of a display device according to still another example embodiment of the present disclosure.

FIG. 9 is an example of a cross-sectional view of B-B′ of FIG. 8.

FIG. 10 is an example of a cross-sectional view of B-B′ of FIG. 8.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, components, electrodes, structures, transistors, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. Any references to singular may include plural, and vice versa, unless expressly stated otherwise. In one or more examples, unless expressly stated otherwise, an element may be one or more elements; and an element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, components, electrodes, structures, transistors, sections, members, parts, regions, areas, portions, and/or the like) are described using any of the terms such as “on,” “on a top of,” “upon,” “on top of,” “over,” “under,” “above,” “upper,” “below,” “lower,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “upper,” “lower,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “following,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” and the like may be used herein to describe various elements (e.g., layers, films, components, electrodes, structures, transistors, sections, members, parts, regions, areas, portions, steps, operations, and/or the like), these elements should not be limited by these terms, for example, to any particular order, precedence, or number of elements. Further, these are not used to define the essence or basis of the elements. These terms are merely used to refer to one element separately from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

The expression that an element (e.g., layer, film, component, electrode, structure, transistor, section, member, part, region, area, portion, or the like) “is engaged” with another element may be understood, for example, as that the element may be either directly or indirectly engaged with the another element. The term “is engaged” or similar expressions may refer to a term such as “covers,” “surrounds,” “is in contact,” “contacts,” “overlaps,” “crosses,” “intersects,” “is connected,” “is coupled,” “is attached,” “is adhered,” “is combined,” “is linked,” “is provided,” “is disposed,” “interacts,” or the like. The engagement may involve one or more intervening elements disposed or interposed between the element and the another element, unless otherwise specified. Further, the element may be engaged at least partially or entirely (or completely) with the another element, unless otherwise specified. Further, the element may be included in at least one of two or more elements that are engaged with each other. Similarly, the another element may be included in at least one of two or more elements that are engaged with each other. When the element is engaged with the another element, at least a portion of the element may be engaged with at least a portion of the another element. The term “with another element” or similar expressions may be understood as “another element,” or “with, to, in, or on another element,” as appropriate by the context. Similarly, the term “with each other” may be understood as “each other,” or “with, to, or on each other,” as appropriate by the context.

The phrase “through” may be understood, for example, to be at least partially through or entirely through.

Unless stated otherwise, the terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally. For example, Unless stated otherwise, the terms “first direction,” “second direction,” “third direction,” “X direction,” “Y direction,” “Z direction,” “bending direction,” “extension direction” and the like should not be interpreted only based on a geometrical relationship in which the respective directions are parallel, perpendicular, diagonal, or slanted with respect to each other, and may be meant as directions having wider directivities within the range within which the components of the present disclosure may operate functionally.

The term “at least one” should be understood as including any and all combinations of one or more of the associated listed items. For example, unless stated otherwise, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, unless stated otherwise, at least one of a plurality of elements can represent (i) one element of the plurality of elements, (ii) some elements of the plurality of elements, or (iii) all elements of the plurality of elements. Further, unless stated otherwise, “at least some,” “some,” “at least some portions,” “at least some parts,” “at least a portion,” “at least one or more portions,” “at least a part,” “at least one or more parts,” “at least some elements,” “one or more,” or the like of a plurality of elements can represent (i) one element of the plurality of elements, (ii) a portion (or a part) of the plurality of elements, (iii) one or more portions (or parts) of the plurality of elements, (iv) one or more elements of the plurality of elements, (v) multiple elements of the plurality of elements, or (vi) all of the plurality of elements. Moreover, unless stated otherwise, “at least some,” “some,” “at least some portions,” “at least some parts,” “at least a portion,” “at least one or more portions,” “at least a part,” “at least one or more parts,” or the like of an element can represent (i) a portion (or a part) of the element, (ii) one or more portions (or parts) of the element, (iii) the element, or (iv) all portions of the element.

The expression of a first element, a second elements “and/or” a third element should be understood as any one of the first, second and third elements or as any or all combinations of the first, second and third elements. Similar interpretations apply to the use of “and/or” with two elements or with more than three elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

A phrase “substantially the same” or “nearly the same” may indicate a degree of being considered as being equivalent to each other taking into account minute differences due to errors in the manufacturing process.

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in more detail with reference to the accompanying drawings. With respect to reference numerals to elements of each of the drawings, the same or similar elements may be illustrated in other drawings, and like reference numerals may refer to like or similar elements unless stated otherwise. The same or similar elements may be denoted by the same reference numerals even if they are depicted in different drawings. Repetitive descriptions of the same or similar elements may be omitted for brevity, and the descriptions provided for elements in one or more figures may also apply to elements in other figures that use the same or similar reference numerals unless stated otherwise. In addition, for the convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

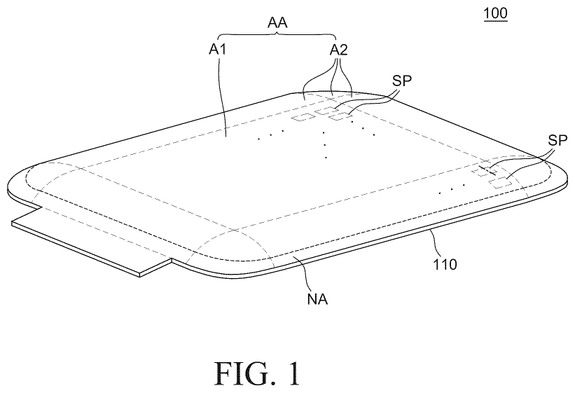

FIG. 1 is a schematic view of a display device according to an example embodiment of the present disclosure. In FIG. 1, for the convenience of description, among various components of the display device 100, only a substrate 110 is illustrated.

Referring to FIG. 1, a display device 100 according to an example embodiment of the present disclosure may include a substrate 110.

The substrate 110 may be a component for supporting various components included in the display device 100. A light emitting element for displaying an image, a driving circuit for driving the light emitting element, and wiring lines for transmitting various signals to the light emitting element and the driving circuit may be disposed on the substrate 110.

In one or more examples, the display device 100 may include a display area AA and a non-display area NA. In one or more examples, the substrate 110 may include the display area AA and the non-display area NA.

The display area AA is an area in which images are displayed. In the active area AA, a plurality of sub pixels SP constituting a plurality of pixels and a driving circuit for driving the plurality of sub pixels SP may be disposed.

The plurality of sub-pixels SP is a minimum unit constituting the display area AA, and a light emitting element may be disposed in each of the plurality of sub-pixels SP. For example, an organic light-emitting element including an anode, an organic light-emitting layer, and a cathode may be disposed in each of the plurality of sub-pixels SP, but it is not limited thereto. Further, a driving circuit for driving the plurality of sub-pixels SP may include a driving element, a wiring line, and the like. For example, the driving circuit may be configured by a thin film transistor, a storage capacitor, a gate line, a data line, and the like, but is not limited thereto.

The display area AA may include a first display area A1 and a second display area A2.

The first display area A1 may be an area formed by or having a flat surface, and the second display area A2 may be an area formed by or having a curved surface. For example, the first display area A1 may be referred to as a flat portion, and the second display area A2 may be referred to as a curved portion or a bending portion. For example, the second display area A2 is disposed in the upper portion, the lower portion, both side portions, and the corner of the first display area A1 so that the slope may increase as the distance from the first display area A1 increases. However, the present disclosure is not limited thereto, and the second display areas A2 disposed on the upper portion, the lower portion, and both side portions of the first display area A1 may be disposed with different curvatures. In addition, the second display area A2 may be disposed on only one side of the first display area A1 or on all sides of the first display area A1. For example, when the first display area A1 has four sides, the second display area A2 may be disposed on one or more sides of four sides, or as shown in FIG. 1, all sides and corners of four sides, but is not limited thereto.

The second display area A2 may be a display area in which the sub-pixels SP are disposed in all or a part of the second display area A2, and the entirety or a part of the second display area A2 may be configured as a part of the display area AA, but is not limited thereto. When only a part of the second display area A2 is configured as the display area AA, the remaining part of the second display area A2 may be configured as a part of the non-display area NA.

The non-display area NA is an area where an image is not displayed. For instance, the non-display area NA may be configured as an outer portion of the substrate 110 surrounding the display area AA or may be configured as an area outside the display area AA. In the non-display area NA, various wiring lines and circuits for driving the organic light emitting elements of the display area AA may be disposed. For example, in the non-display area NA, a link line for transmitting signals to the plurality of sub pixels SP and the driving circuit of the display area AA or a driving integrated circuit (IC) D-IC, such as a gate driver IC and a data driver IC may be disposed, but it is not limited thereto. The non-display area NA may extend from the second display area A2 formed as (or having) a curved surface. The inclination of the non-display area NA may increase as the distance from the second display area A2 increases. In one or more examples, a driving circuitry may include or may refer to a driving IC.

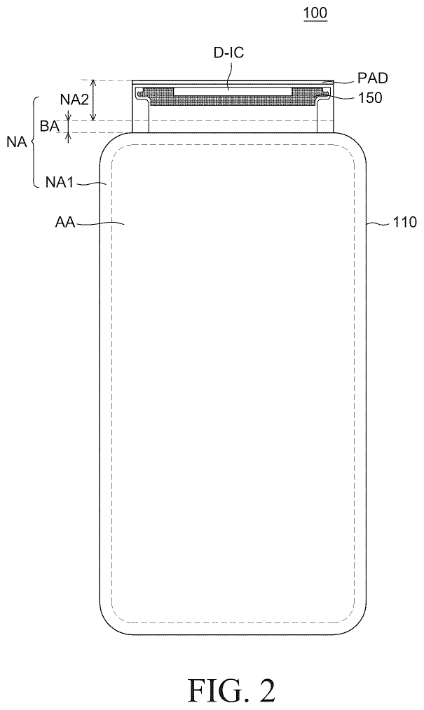

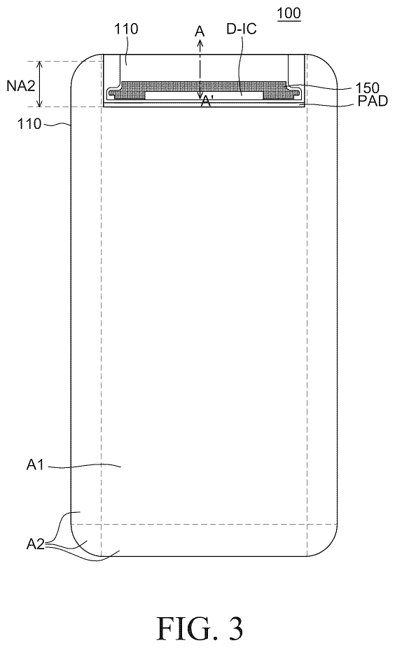

FIG. 2 is a plan view of the display device according to the example embodiment of the present disclosure before bending. FIG. 3 is a rear view of the display device according to the example embodiment of the present disclosure after bending. FIG. 2 illustrates a front surface of the substrate 110 before bending, and FIG. 3 illustrates a rear surface of the substrate 110 after bending.

Referring to FIGS. 2 and 3, the substrate 110 may include a display area AA and a non-display area NA.

The non-display area NA may include a first non-display area NA1, a bending area BA, and a second non-display area NA2.

The first non-display area NA1 may be an area that surrounds the display area AA and extends from the display area AA.

The bending area BA is an area extending from one side of the first non-display area NA1 and may be an area bent in a bending direction.

The second non-display area NA2 may be an area extending from the bending area BA and disposed below the substrate 110 during bending of after bending. A driving IC D-IC, a pad part PAD, and a reinforcement plate 150 may be disposed in the second non-display area NA2.

The driving IC D-IC may provide a data signal to the plurality of sub-pixels SP. For example, the driving IC D-IC may change the data signal supplied from the timing controller into an analog form and output the analog form in response to the data timing control signal supplied from the timing controller. The driving IC D-IC may output data signals through a plurality of data lines. Meanwhile, the driving IC D-IC may be disposed on one side of the substrate 110 in a chip on panel (COP) form to be connected to the substrate 110 or a chip on film (COF) form disposed on a separate flexible film to be connected to the substrate 110. In the display device 100 according to the example embodiment of the present disclosure, it is assumed that the driving IC D-IC is disposed in a COP form, but it is not limited thereto.

In the pad part PAD, a flexible circuit board is connected to provide various signals and voltages to the driving IC D-IC and the plurality of sub-pixels SP.

The reinforcement plate 150 may be disposed in the second non-display area NA2 of the substrate 110 to support the second non-display area NA2. In addition, the reinforcement plate 150 may be disposed in the second display area A2 to support the second display area A2. A plurality of holes 154 may be disposed in the reinforcement plate 150.

Both sides of the reinforcement plate 150 may be curved along (or conforming to or corresponding to) the shapes of the bending area BA and the second non-display area NA2 of the substrate 110, but are not limited thereto.

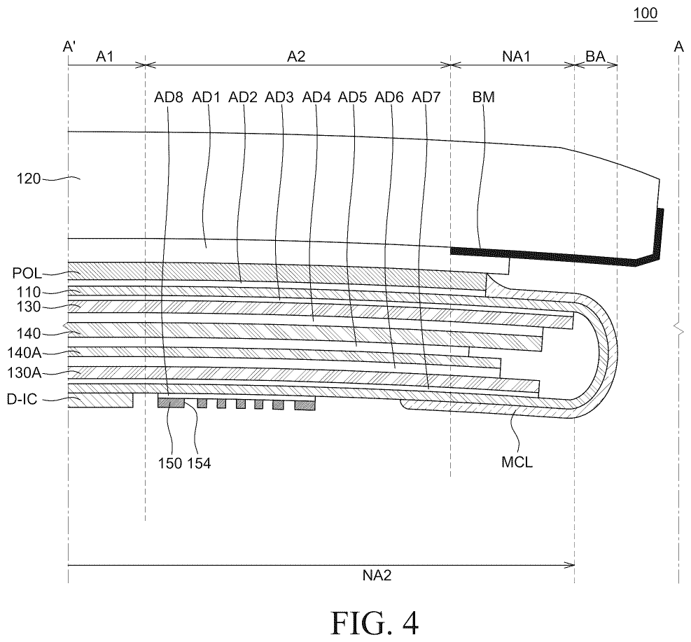

FIG. 4 is an example of a cross-sectional view taken along the line A-A′ of FIG. 3.

Referring to FIG. 4, the display device 100 according to one or more aspects of the present disclosure may include a substrate 110, a cover window 120, a polarizer POL, a back plate 130, a metal plate 140, a reinforcement plate 150, and a micro coating layer MCL.

The substrate 110 is a component for supporting various components included in the display device 100 and may be made of an insulating material. For example, the substrate 110 may be a glass substrate made of a plastic material such as polyimide (PI) or glass.

The cover window 120 may be disposed on the front surface of the substrate 110. The cover window 120 may be a component exposed from the outside of the display device 100 and protects the display device 100 from external impacts and scratches. Further, the cover window 120 may protect the display device 100 from moisture permeating from the outside. The cover window 120 may be formed of glass or a plastic material having flexibility, but is not limited thereto.

A black matrix BM is disposed below the cover window 120. The black matrix BM may be disposed along the circumference of the cover window 120 at the outer periphery of the cover window 120. The black matrix BM may be formed of a material having low permeability. Accordingly, the black matrix BM may prevent various components disposed under the black matrix BM from being visually recognized to the outside. Further, the black matrix BM may be formed of a conductive material to discharge static electricity of the cover window 120.

The black matrix BM may be composed of chromium (Cr), graphite, or resin containing conductive particles. Here, the resin may be formed of one or more materials of acrylic resin, epoxy resin, phenolic resin, polyamides resin, polyimides resin, unsaturated polyesters resin, polyphenylene resin, polyphenylenesulfides resin, and benzocyclobutene, but is not limited thereto. In addition, the conductive particles may be formed of any one of molybdenum (Mo), chromium (Cr), titanium (Ti), nickel (Ni), neodymium (Nd), copper (Cu), and an alloy of silver (Ag) and magnesium (Mg), but are not limited thereto.

A polarizing plate POL may be disposed between the substrate 110 and the cover window 120. The polarization plate POL may be disposed on the entire surface of the substrate 110. The polarization plate POL selectively transmits light to reduce reflection of external light incident on the substrate 110. Specifically, the substrate 110 may include various metal materials applied to semiconductor devices, wiring lines, organic light emitting devices, and the like. Therefore, the external light incident onto the substrate 110 may be reflected from the metal material, and the visibility of the display device 100 may be reduced due to the reflection of the external light. On the other hand, when the polarization plate POL is disposed, the polarization plate POL suppresses the reflection of external light to increase the outdoor visibility of the display device 100. However, the polarization plate POL may be omitted depending on the design of the display device 100, but is not limited thereto.

The first adhesive layer AD1 may be disposed between the polarization plate POL and the cover window 120, and the second adhesive layer AD2 may be disposed between the polarization plate POL and the substrate 110. The first adhesive layer AD1 may bond the cover window 120 and the polarization plate POL, and the second adhesive layer AD2 may bond the polarization plate POL and the substrate 110. The first adhesive layer AD1 and the second adhesive layer AD2 may be formed of a transparent adhesive layer so that the image of the substrate 110 is visible. For example, the first adhesive layer AD1 and the second adhesive layer AD2 may be formed of an optical clear adhesive (OCA), but are not limited thereto.

The back plate 130 may be disposed below the substrate 110. The back plate 130 may be disposed to support the substrate 110. For example, when the substrate 110 is made of a plastic material such as polyimide, a separate component for protecting the substrate 110 may be required due to the flexible characteristics. Accordingly, a support substrate made of glass is disposed under the substrate 110 to perform a manufacturing process of the display device 100, and after the manufacturing process is completed, the support substrate may be separated and released. However, since a component for supporting the substrate 110 is required even after the support substrate is released, the back plate 130 for supporting the substrate 110 may be disposed below the substrate 110.

The back plate 130 may include a plastic material. For example, the back plate 130 may be formed of a plastic thin film formed of polyimide (PI), polyethylene naphthalate (PEN), polyethylene terephthalate (PET), or a combination of these polymers.

A third adhesive layer AD3 is disposed between the substrate 110 and the back plate 130. The third adhesive layer AD3 may bond the substrate 110 and the back plate 130. The third adhesive layer AD3 may be formed of a pressure sensitive adhesive (PSA), but is not limited thereto.

The metal plate 140 may be disposed below the back plate 130.

The metal plate 140 may protect the components of the display device 100 from external impacts. Further, the metal plate 140 serves as a ground to suppress static electricity permeating into the display device 100 or to easily discharge residual electric charges accumulated in the display device 100 to the outside. In addition, the metal plate 140 may easily dissipate heat generated from the display device 100 to the outside. The metal plate 140 may be formed of a metal material having excellent thermal conductivity, electrical conductivity, and mechanical rigidity. For example, the metal plate 140 may be made of copper (Cu) or stainless steel (SUS), but is not limited thereto.

A fourth adhesive layer AD4 may be disposed between the back plate 130 and the metal plate 140. The fourth adhesive layer AD4 may bond the back plate 130 and the metal plate 140. The fourth adhesive layer AD4 may be made of pressure sensitive adhesive (PSA), but is not limited thereto.

The additional back plate 130A and the additional metal plate 140A may be disposed below the metal plate 140. The additional metal plate 140A may be disposed below the metal plate 140, and the additional back plate 130A may be disposed below the additional metal plate 140A.

The additional back plate 130A and the additional metal plate 140A may be disposed in the second non-display area NA2 of the substrate 110 to reinforce the rigidity of the second non-display area NA2. Meanwhile, the additional back plate 130A and the additional metal plate 140A may be disposed so as not to overlap the bending area BA. Accordingly, the thickness of the components disposed in the bending area BA may be minimized, and the neutral plane of the bending area BA may be easily controlled, thereby securing the flexibility of the bending area BA.

The fifth adhesive layer AD5 may be disposed between the metal plate 140 and the additional metal plate 140A, and the sixth adhesive layer AD6 may be disposed between the additional metal plate 140A and the additional back plate 130A. The fifth adhesive layer AD5 may bond the metal plate 140 and the additional metal plate 140A, and the sixth adhesive layer AD6 may bond the additional metal plate 140A and the additional back plate 130A. For example, the fifth adhesive layer AD5 and the sixth adhesive layer AD6 may be formed of pressure sensitive adhesive (PSA), but are not limited thereto.

A second non-display area NA2 of the bent substrate 110 may be disposed below the additional back plate 130A. Further, a seventh adhesive layer AD7 may be disposed between the additional back plate 130A and the second non-display area NA2 of the substrate 110. The seventh adhesive layer AD7 may bond the additional back plate 130A and the second non-display area NA2 of the substrate 110. For example, the seventh adhesive layer AD7 may be formed of pressure sensitive adhesive (PSA), but is not limited thereto.

A micro coating layer MCL may be disposed in the bending area BA of the substrate 110.

The micro coating layer MCL may be a component for protecting components disposed in the bending area BA of the substrate 110, for example, various wiring lines. A tensile force is applied to the bending area BA of the substrate 110 so that components may be cracked. Therefore, the micro coating layer MCL is coated on the components disposed in the bending area BA of the substrate 110 with a thin thickness to protect the components disposed in the bending area BA. The micro coating layer MCL may be formed of resin and for example, may be formed of an acrylic material such as acrylate polymer, but is not limited thereto.

The reinforcement plate 150 may be disposed below the additional back plate 130A. Further, an eighth adhesive layer AD8 may be disposed between the substrate 110 and the reinforcement plate 150. The eighth adhesive layer AD8 may bond the substrate 110 and the reinforcement plate 150. For example, the eighth adhesive layer AD8 may be made of pressure sensitive adhesive (PSA), but is not limited thereto.

Hereinafter, the reinforcement plate 150 will be described in detail with reference to the drawings.

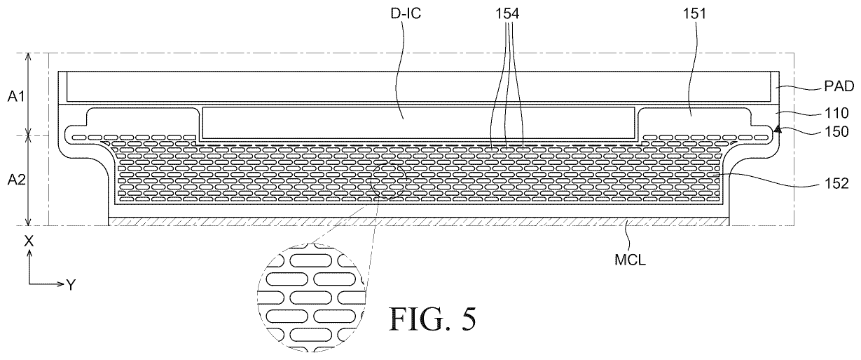

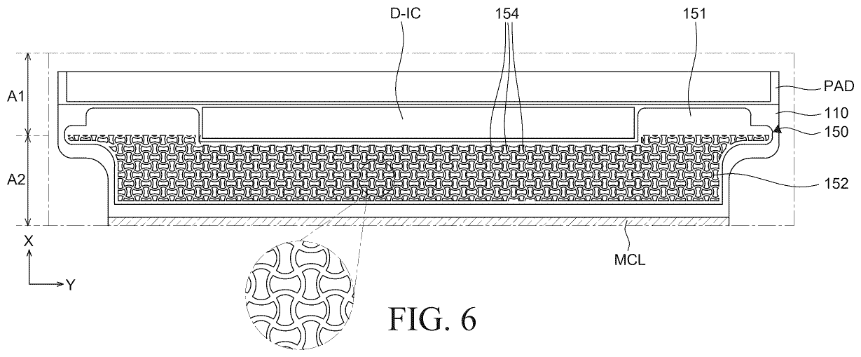

FIG. 5 is an example of an enlarged plan view of a reinforcement plate of FIG. 3 and a part of a substrate on which the reinforcement plate is disposed. FIG. 6 is an example of a plan view illustrating another shape of the reinforcement plate.

Referring to FIGS. 4 and 5, the reinforcement plate 150 may be disposed in the second non-display area NA2 of the substrate 110 to support the second non-display area NA2. The driving IC D-IC may be disposed between the reinforcement plate 150 and the pad part PAD. The reinforcement plate 150 may be made of a material having rigidity to reinforce the substrate 110 having a flexible characteristic. For example, the reinforcement plate 150 may be made of a metal such as copper (Cu) or stainless steel (SUS), but is not limited thereto.

The reinforcement plate 150 may include a first portion 151 and a second portion 152.

The first portion 151 may overlap the first display area A1. The first portion 151 may have a flat shape, may be flat, or may include a flat portion or a flat area. The first portion 151 may have a planar shape corresponding to (or conforming to) the first display area A1. The first portion 151 may be disposed to surround both side portions of the driving IC D-IC. Therefore, the first portion 151 may reinforce the first display area A1, which is a flat area of the substrate 110, and reinforce both side portions of the driving IC D-IC to minimize damage to the driving IC D-IC.

The second portion 152 may extend from the first portion 151 and may be disposed to be bent. The second portion 152 may overlap the second display area A2. The second portion 152 may be formed in a curved shape or may include a curved portion or a curved area corresponding to the substrate 110 in the second display area A2. The second portion 152 may be bent to correspond to (or conform to) the bent substrate 110 in the second display area A2.

A plurality of holes 154 may be disposed in the second portion 152.

The plurality of holes 154 may allow the reinforcement plate 150 to have flexibility. The plurality of holes 154 may be disposed in the second portion 152 to be spaced apart from each other by a predetermined interval in the first direction (X direction) and the second direction (Y direction).

A plurality of holes 154 may be alternately disposed with a plurality of holes 154 disposed adjacent to each other in the first direction. Specifically, centers of a plurality of holes 154 disposed adjacent to each other in the first direction may be alternately disposed.

In some examples, the plurality of holes 154 may be arranged in multiple rows in a staggered pattern, with alternating rows having aligned centers. In an example, the plurality of holes 154 may be arranged in multiple rows, with the centers of the plurality of holes 154 in adjacent rows staggered so that alternate rows are aligned. In an example, the plurality of holes 154 may be disposed in multiple rows in an alternating, staggered arrangement, such that the centers of the plurality of holes 154 in alternate rows align while the centers the plurality of holes 154 in the intermediate rows are offset.

The planar shape of the plurality of holes 154 may be a shape extending in a direction (Y direction) orthogonal to the bending direction (X direction). For example, the plurality of holes 154 may be aligned parallel to the extending direction of the driving IC D-IC. For example, a planar shape of each of the plurality of holes 154 may be an oval shape, a Bunimovich Stadium shape, a rectangular shape, or the like. In addition, as shown in FIG. 6, it may be formed in a radial pattern shape or an orthogonal pattern shape.

In the case of a display device in which a bezel area is bent in a curved shape, stress is increased in the bent bezel area so that wiring and an insulating layer constituting a substrate of the display device are peeled off or a reinforcement plate adhered to the substrate is peeled off.

Accordingly, in the display device 100 according to the example embodiment of the present disclosure, the reinforcement plate 150 is disposed in the second non-display area NA2 of the substrate 110, and the reinforcement plate 150 is composed of a first portion 151 overlapping the planar first display area A1 and a second portion 152 overlapping the curved second display area A2. A plurality of holes 154 are formed in the second portion 152 but not in the first portion 151. Accordingly, when the substrate 110 overlapping the second display area A2 is bent to correspond to the curved shape of the second display area A2, the second part 152 is also bent in the same manner. In this case, while deformation is facilitated by the plurality of holes 154, it is possible to minimize the occurrence of stress due to deformation. Accordingly, in the display device 100 according to the example embodiment of the present disclosure, a plurality of holes 154 are formed in the reinforcement plate 150 disposed in an area in which the bezel area is bent in a curved shape to minimize the stress applied to the bezel area even though the bezel area of the display device 100 is bent in a curved shape. Therefore, it is possible to minimize the concentration of stress on only a partial area (or a localized area) of the bezel area to suppress the peeling of each component of the display device 100 and improve the reliability of the display device 100.

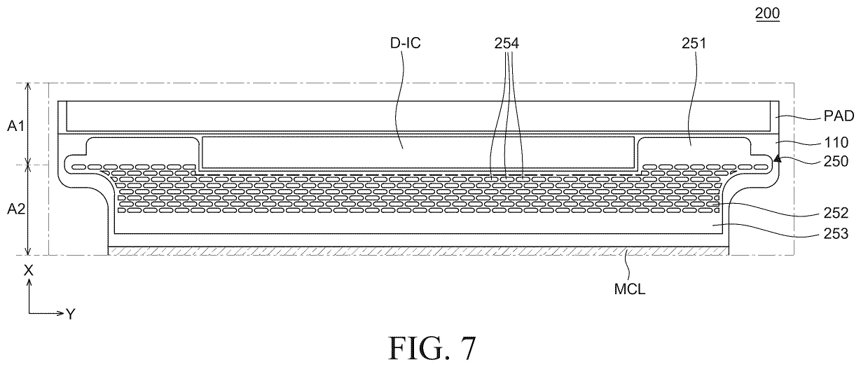

FIG. 7 is a plan view of a display device according to another example embodiment of the present disclosure. FIG. 7 illustrates a portion of the reinforcement plate 250 and the substrate 110 on which the reinforcement plate 250 is disposed. In FIG. 7, the remaining configurations excluding the reinforcement plate 250 are the same as those in FIGS. 1 to 6. Therefore, the descriptions provided for the display device 100 and its components with respect to FIGS. 1 to 6 apply to the display device 200 and its components of FIG. 7 (excluding the reinforcement plate 250), and a redundant description is omitted for brevity. It should be noted that some of the descriptions of the reinforcement plate 150 may apply to the reinforcement plate 250, except as otherwise described with respect to the reinforcement plate 250.

Referring to FIG. 7, the driving IC D-IC of the display device 200 according to another example embodiment of the present disclosure may be disposed between the reinforcement plate 250 and the pad part PAD.

The reinforcement plate 250 may include a first portion 251, a second portion 252, and a third portion 253.

The first portion 251 may overlap the first display area A1. The first portion 251 may have a flat shape. The first portion 251 may have a planar shape corresponding to the first display area A1. The first portion 251 may be disposed to surround both side portions of the driving IC D-IC. Therefore, the second portion 251 may reinforce the first display area A1, which is a flat area of the substrate 110, and reinforce both side portions of the driving IC D-IC to minimize damage to the driving IC D-IC.

The second portion 252 may extend from the first portion 251 and may be disposed to be bent. The second portion 252 may overlap the second display area A2. The second portion 252 may be formed in a curved shape corresponding to the second display area A2.

A plurality of holes 254 may be disposed in the second portion 252. The plurality of holes 254 may allow the reinforcement plate 250 to have flexibility. The plurality of holes 254 may be disposed in the second portion 252 to be spaced apart from each other by a predetermined interval in the first direction (X direction) and the second direction (Y direction).

A plurality of holes 254 may be alternately disposed with a plurality of holes 254 disposed adjacent to each other in the first direction. Specifically, centers of a plurality of holes 254 disposed adjacent to each other in the first direction may be alternately disposed.

The planar shape of the plurality of holes 254 may be a shape extending in a direction (Y direction) orthogonal to the bending direction (X direction). For example, the plurality of holes 254 may be aligned parallel to the extending direction of the driving IC D-IC. For example, a planar shape of the plurality of holes 254 may be an oval shape, a Bunimovich Stadium shape, a radial pattern shape, or an Orthogonal pattern shape.

The third portion 253 may extend from the second portion 252 and be disposed to be bent. In the third portion 253, a plurality of holes 254 may not be disposed. The third portion 253 may be disposed to overlap the second display area A2 and disposed in a curved shape. The third portion 253 may be disposed adjacent to a boundary between the second display area A2 and the first non-display area NA1. The third portion 253 may be disposed adjacent to the micro coating layer MCL.

Accordingly, in the display device 200 according to another example embodiment of the present disclosure, a plurality of holes 254 are formed in the reinforcement plate 250 disposed in an area in which the bezel area is bent in a curved shape to minimize the stress applied to the bezel area even though the bezel area of the display device 200 is bent in a curved shape. By minimizing concentration of stress on only a partial area of the bezel area, peeling of each component of the display device 200 may be prevented, and the reliability of the display device 200 may be improved.

On the other hand, in the case of a display device in which the bezel area is bent in a curved shape, when an external impact is applied, there is a problem in that the impact is concentrated in an area corresponding to the end of the substrate in the bezel area and stress is concentrated only in a partial area.

Accordingly, in the display device 200 according to another example embodiment of the present disclosure, the reinforcement plate 250 is disposed in the second non-display area NA2 of the substrate 210. The reinforcement plate 250 includes a first portion 251 that overlaps the planar first display area A1, a second portion 252 that overlaps the curved second display area A2, and a third portion 253 that extends from the second portion 252 and has a curved shape. A plurality of holes 254 are formed in the second portion 252, and a plurality of holes 254 are not formed in the first portion 251 and the third portion 253. Accordingly, when the substrate 110 overlapping the second display area A2 is bent to correspond to the curved shape of the second display area A2 of the substrate 110, the second portion 252 is also bent in the same manner. In this case, the plurality of holes 254 facilitates deformation, thereby minimizing the occurrence of stress due to deformation in the reinforcement plate 250. Further, the third portion 253 in which the plurality of holes 254 is not formed is disposed adjacent to the end of the display device 200 to minimize the concentration of stress on only a partial area of the bezel area corresponding to the end of the display device 200 in the event of an external impact, thereby preventing the peeling of each component of the display device 200 and improving the reliability of the display device 200. Accordingly, in the display device 200 according to another example embodiment of the present disclosure, the third portion 253 in which the plurality of holes 254 is not formed is disposed so as to correspond to the edge of the display device 200 to ensure rigidity. Therefore, it is possible to minimize the concentration of impact on the edge of the display device 200 even with an external impact, thereby minimizing damage to the display device.

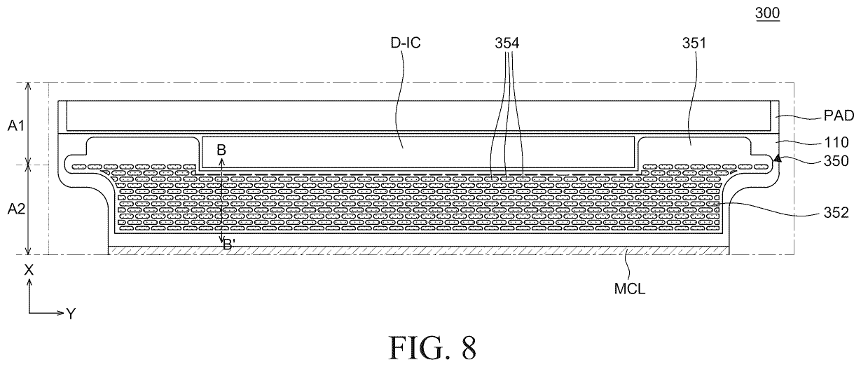

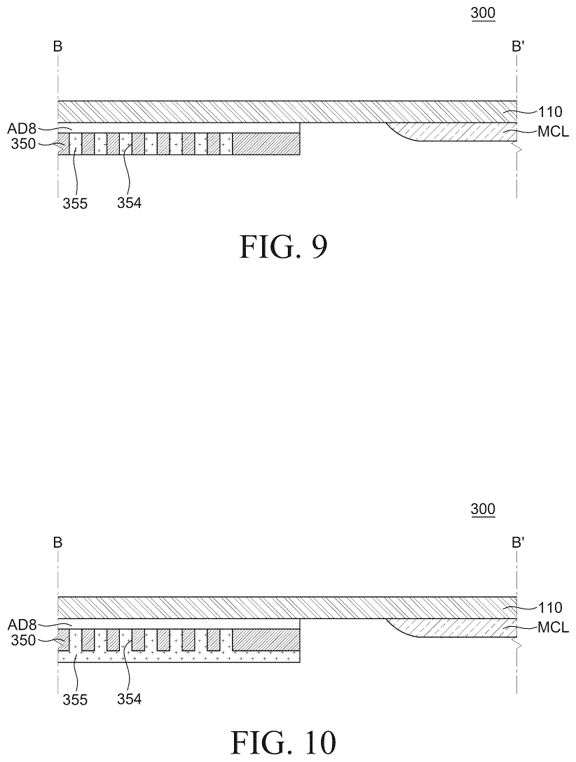

FIG. 8 is a plan view of a display device according to still another example embodiment of the present disclosure. FIGS. 9 and 10 are examples of cross-sectional views of B-B′ of FIG. 8. FIG. 8 illustrates a part of the reinforcement plate 350 and the substrate 110 on which the reinforcement plate 350 is disposed. In FIGS. 8 to 10, the remaining configurations excluding the reinforcement plate 350 are the same as those in FIGS. 1 to 7. Therefore, the descriptions provided for the display device 100 and 200 and its components with respect to FIGS. 1 to 7 apply to the display device 300 and its components of FIGS. 8-10 (excluding the reinforcement plate 350), and a redundant description is omitted for brevity. It should be noted that some of the descriptions of the reinforcement plate 150 and 250 may apply to the reinforcement plate 350, except as otherwise described with respect to the reinforcement plate 350. FIG. 10 is a view illustrating another shape of the sealing member 355 of FIG. 9.

Referring to FIG. 8, the driving IC D-IC of the display device 300 according to still another example embodiment of the present disclosure may be disposed between the reinforcement plate 350 and the pad part PAD.

The reinforcement plate 350 may include a first part 351 which overlaps the first display area A1 and is disposed in a flat shape, and a second part 352 which extends from the first part 351 and is disposed to be bent while overlapping the second display area A2.

A plurality of holes 354 may be disposed in the second portion 352 of the reinforcement plate 350.

The sealing member 355 may be filled in the plurality of holes 354. The sealing member 355 may be formed by a process of filling and curing the inside of the plurality of holes 354 with a material forming the sealing member 355. For example, the sealing member 355 may be formed of one or more of acrylic resin, epoxy resin, phenolic resin, polyamides resin, polyimides resin, unsaturated polyesters resin, polyphenylene resin, polyphenylenesulfides resin, and benzocyclobutene, but is not limited thereto.

Meanwhile, referring to FIGS. 4, 9 and 10, the sealing member 355 may fill a plurality of holes 354 of the reinforcement plate 350, and may also be disposed on the reinforcement plate 350. For example, the sealing member 355 may fill the inside of the plurality of holes 354 of the reinforcement plate 350 and may also be disposed on the lower surface of the reinforcement plate 350. In some examples, referring to FIGS. 4 to 7, the sealing member 355 may fill any of the plurality of holes 154 and 254.

Accordingly, in the display device 300 according to still another example embodiment of the present disclosure, a plurality of holes 354 are formed in the reinforcement plate 350 disposed in an area in which the bezel area is bent in a curved shape to minimize the stress applied to the bezel area even though the bezel area of the display device 300 is bent in a curved shape. Further, it is possible to minimize the concentration of stress on only a partial area of the bezel area to suppress the peeling of each component of the display device 300 and improve the reliability of the display device 300.

Further, in the display device 300 according to still another example embodiment of the present disclosure, the plurality of holes 354 of the reinforcement plate 350 may be filled with the sealing member 355. Further, the plurality of holes 354 of the reinforcement plate 350 is filled with the sealing member 355, and the sealing member 355 may also be disposed on the reinforcement plate 350. Accordingly, the display device 300 according to still another example embodiment of the present disclosure may prevent moisture permeation through the plurality of holes 354, reinforce the rigidity of the reinforcement plate 350, and enhance the adhesive force of the reinforcement plate 350.

Referring to FIGS. 5 to 10, in some examples, a second portion of a reinforcement plate having a plurality of holes is more flexible than a first portion or a third portion of the reinforcement plate. For example, a second portion 152, 252 or 352 of a respective reinforcement plate 150, 250 or 350 that contains a respective plurality of holes 154, 254 or 354 is more flexible than a respective first portion 151, 251 or 351 or a respective third portion 253.

Various examples and aspects of the present disclosure are described below. These are provided as examples, and do not limit the scope of the present disclosure.

According to one or more example embodiments of the present disclosure, a display device includes a substrate, a display area in which a plurality of pixels is disposed, a first non-display area outside the display area, a bending area extending from one side of the first non-display area, a second non-display area connected to the bending area, a driving circuitry disposed on the substrate in the second non-display area, and a reinforcement plate disposed on the substrate in the second non-display area and surrounding the side portion of the driving circuitry, and the reinforcement plate includes a first portion which is flat, and a second portion which extends from the first portion and is bent, and in which a plurality of holes are disposed.

According to one or more aspects of the present disclosure, the display area may include a first display area having a flat surface and a second display area having a curved surface, the first portion may overlap the first display area, and the second portion may overlap the second display area.

According to one or more aspects of the present disclosure, the reinforcement plate may further include a third portion which extends from the second portion and is bent and in which a plurality of holes are not disposed.

According to one or more aspects of the present disclosure, the second display area may be bent in a first direction, and the plurality of holes may be disposed along an extension direction that is orthogonal to the first direction.

According to one or more aspects of the present disclosure, the plurality of holes may extend along an extending direction, and the driving circuitry may extend along an extending direction that is parallel to the extending direction of the plurality of holes.

According to one or more aspects of the present disclosure, the plurality of holes may be arranged in multiple rows in a staggered pattern, with alternating rows having aligned centers.

According to one or more aspects of the present disclosure, the plurality of holes may be formed in any one of an elliptical shape, a Bunimovich Stadium shape, a rectangular shape, a radial pattern shape, and an orthogonal pattern shape.

According to one or more aspects of the present disclosure, the display device may further comprise a sealing member filling the plurality of holes.

According to one or more aspects of the present disclosure, the sealing member may be disposed on the reinforcement plate.

A display device according to one or more example embodiments of the present disclosure includes a substrate, a display area including a first display area having a flat surface and a second display area having a curved surface, a first non-display area outside the display area, a bending area extending from the first non-display area, a second non-display area extending from the bending area, a micro coating layer disposed in the first non-display area, the bending area, and the second non-display area on the substrate, and a reinforcement plate disposed in the second non-display area on the substrate, spaced apart from the micro coating layer, and having a plurality of holes disposed in an area overlapping the second display area.

According to one or more aspects of the present disclosure, the reinforcement plate may include a first part overlapping the first display area and disposed flat, a second part extending from the first part, disposed to be bent, and having a plurality of holes, and a third part which extends from the second part, which is bent, and in which a plurality of holes are not disposed.

According to one or more aspects of the present disclosure, the second display area may be bent in a first direction, and the plurality of holes may be disposed along an extension direction that is orthogonal to the first direction.

According to one or more aspects of the present disclosure, the display device may further include a sealing member filling a plurality of holes.

A display device according to one or more example embodiments of the present disclosure comprises a display area configured to display an image, and a non-display area outside the display area, wherein the non-display area comprises a first non-display area extending from the display area, a bending area extending from the first non-display area, and a second non-display area extending from the bending area, and wherein the display device further comprises a substrate overlapping the non-display area, and a reinforcement plate disposed on the substrate, the reinforcement plate having a first part and a second part, the second part having a flexibility greater than a flexibility of the first part.

According to one or more aspects of the present disclosure, the second part may include a plurality of holes, and the first part does not include the plurality of holes.

According to one or more aspects of the present disclosure, the substrate may overlap the first non-display area, the bending area, and the second non-display area, and the reinforcement plate may overlap the second non-display area and does not overlap the first non-display area or the bending area.

According to one or more aspects of the present disclosure, the display area may include a first display area having a flat surface and a second display area having a curved surface, and the reinforcement plate may overlap the substrate in the second display area and the substrate in the second non-display area.

According to one or more aspects of the present disclosure, the display device may further comprise a driving circuitry on the substrate, and a micro coating layer on the substrate, and the reinforcement plate may be disposed between the driving circuitry and the micro coating layer.

Although the example embodiments of the present disclosure have been described in detail with reference to the accompanying drawings, the present disclosure is not limited thereto and may be embodied in various forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present invention. The protective scope of the present disclosure should be construed based on the following claims, and all the technical concepts in the equivalent scope thereof should be construed as falling within the scope of the present disclosure.

What is claimed is:

1. A display device, comprising:
a substrate;
a display area in which a plurality of pixels is disposed, a first non-display area outside the display area, a bending area extending from one side of the first non-display area and bent, and a second non-display area connected to the bending area;
a driving circuitry disposed on the substrate in the second non-display area; and
a reinforcement plate disposed on the substrate in the second non-display area and surrounding a side portion of the driving circuitry,
wherein the reinforcement plate includes:
a first portion which is flat; and
a second portion which extends from the first portion and is bent, and in which a plurality of holes are disposed.

2. The display device according to claim 1, wherein the display area includes a first display area having a flat surface and a second display area having a curved surface,
wherein the first portion overlaps the first display area, and
wherein the second portion overlaps the second display area.

3. The display device according to claim 1, wherein the reinforcement plate is disposed to be bent while extending from the second portion and further includes a third portion in which a plurality of holes are not disposed.

4. The display device according to claim 2, wherein the second display area is bent in a first direction, and
wherein the plurality of holes are disposed along an extension direction that is orthogonal to the first direction.

5. The display device according to claim 1, wherein the plurality of holes extend along an extending direction, and
wherein the driving circuitry extends along an extending direction that is parallel to the extending direction of the plurality of holes.

6. The display device according to claim 1, wherein the plurality of holes are arranged in multiple rows in a staggered pattern, with alternating rows having aligned centers.

7. The display device according to claim 1, wherein a planar shape of the plurality of holes are any one of an oval shape, a Bunimovich Stadium shape, a rectangular shape, a radial pattern shape, and an orthogonal pattern shape.

8. The display device according to claim 1, further comprising:
a sealing member filling the plurality of holes.

9. The display device according to claim 8, wherein the sealing member is disposed on the reinforcement plate.

10. A display device, comprising:
a substrate;
a display area including a first display area having a flat surface and a second display area having a curved surface, a first non-display area outside the display area, a bending area extending from the first non-display area, and a second non-display area extending from the bending area;
a micro coating layer disposed on the substrate in the first non-display area, the bending area, and the second non-display area; and
a reinforcement plate disposed on the substrate in the second non-display area, spaced apart from the micro coating layer, and having a plurality of holes disposed in an area overlapping the second display area.

11. The display device according to claim 10, wherein the reinforcement plate includes:
a first part which overlaps the first display area and is disposed flat;
a second part which extends from the first part, which is being bent, and in which the plurality of holes are disposed; and
a third part which extends from the second part, which is being bent, and in which the plurality of holes are not disposed.

12. The display device according to claim 10, wherein the second display area is bent in a first direction, and
wherein the plurality of holes are disposed along an extension direction that is orthogonal to the first direction.

13. The display device according to claim 10, further comprising a sealing member filling the plurality of holes.

14. A display device, comprising:
a display area configured to display an image;
a non-display area outside the display area, the non-display area comprising a first non-display area extending from the display area, a bending area extending from the first non-display area, and a second non-display area extending from the bending area;
a substrate overlapping the non-display area; and
a reinforcement plate disposed on the substrate and having a first part and a second part, the second part having a flexibility greater than a flexibility of the first part.

15. The display device according to claim 14, wherein the second part includes a plurality of holes, and
wherein the first part does not include the plurality of holes.

16. The display device according to claim 14, wherein the substrate overlaps the first non-display area, the bending area, and the second non-display area, and
wherein the reinforcement plate overlaps the second non-display area and does not overlap the first non-display area or the bending area.

17. The display device according to claim 14, wherein the display area includes a first display area having a flat surface and a second display area having a curved surface, and
wherein the reinforcement plate overlaps the substrate in the second display area and the substrate in the second non-display area.

18. The display device according to claim 14, further comprising:
a driving circuitry on the substrate; and
a micro coating layer on the substrate,
wherein the reinforcement plate is disposed between the driving circuitry and the micro coating layer.
